(19) United States
(12) Patent Application Publication
(10) Pub. No.: US 2023/0178346 A1
(43) Pub. Date: Jun. 8, 2023

(54) SCANNING RADICAL SENSOR USABLE FOR MODEL TRAINING

(71) Applicant: Applied Materials, Inc., Santa Clara, CA (US)

(72) Inventors: Stephen Moffatt, St. Brelade (JE); Martin Hilkene, Gilroy, CA (US)

(21) Appl. No.: 17/545,618

(22) Filed: Dec. 8, 2021

(51) Int. Cl. H01J 37/32; H01L 21/67; G06F 30/20; H01L 21/66

(52) U.S. Cl. CPC H01J 37/32963; H01L 21/67253; H01J 37/32926; G06F 30/20; H01L 22/10

(57) ABSTRACT

In an embodiment, a plasma processing tool with an extendable probe is described. In an embodiment, the plasma processing tool comprises a chamber, and a pedestal for supporting a substrate. In an embodiment, an edge ring is around a perimeter of the pedestal. Additionally, a sensor at an end of a probe is provided. In an embodiment, the probe is configured to extend over the pedestal.

### BACKGROUND

### 1) Field

Embodiments relate to the field of semiconductor manufacturing and, in particular, to a method and apparatus for measuring radicals in a plasma process and using the recorded information to build a plasma model for a digital twin.

### 2) Description of Related Art

Semiconductor wafer processing has been increasing in complexity as semiconductor devices continue to scale to smaller feature sizes. A given process may include many different processing parameters (i.e., knobs) that can be individually controlled in order to provide a desired outcome on the wafer. For example, the desired outcome on the wafer may refer to a feature profile, a thickness of a layer, a chemical composition of a layer, or the like. As the number of knobs increase, the theoretical process space available to tune and optimize the process grows exceedingly large.

Additionally, once the final processing recipe has been developed, chamber drift during many iterations of the process for different wafers may result in changes to the outcome on the wafer. Chamber drift may be the result of erosion of consumable portions of the chamber, degradation of components (e.g., sensors, lamps, etc.), deposition of byproduct films over surfaces, or the like. Accordingly, additional tuning is needed even after the extensive recipe development process.

### SUMMARY

In an embodiment, a plasma processing tool with an extendable probe is described. In an embodiment, the plasma processing tool comprises a chamber, and a pedestal for supporting a substrate. In an embodiment, an edge ring is around a perimeter of the pedestal. Additionally, a sensor at an end of a probe is provided. In an embodiment, the probe is configured to extend over the pedestal.

In an embodiment, methods disclosed herein include a method of training a plasma behavior model. In an embodiment, the method comprises scanning a sensor within a plasma chamber to develop a two-dimensional radical map during a plasma process. The method may further comprise obtaining plasma parameters of the plasma process, and combining the two-dimensional radical map with the plasma parameters to train the plasma behavior model.

In an embodiment, processing tools disclosed herein may further comprise a chamber and a pedestal for supporting a substrate. The processing tool may further comprise an edge ring around a perimeter of the pedestal. In an embodiment, a sensor is provided at an end of a probe. In an embodiment, the probe is configured to extend over the pedestal. The tool may further comprise a plasma behavior model. In an embodiment, the plasma behavior model is trained by a process, comprising scanning the sensor across the pedestal to develop a two-dimensional radical map during a plasma process and obtaining plasma parameters of the plasma process. In an embodiment, the method may further comprise combining the two-dimensional radical map with the plasma parameters to train the plasma behavior model.

### BRIEF DESCRIPTION OF THE DRAWINGS

FIG. 1A is a perspective view illustration of a portion of a chamber with a telescoping probe with a sensor at the end of the probe over a substrate, in accordance with an embodiment.

FIG. 1B is a perspective view illustration of a portion of a chamber with a plurality of telescoping probes with sensors, in accordance with an embodiment.

FIG. 1C is a perspective view illustration of a portion of a chamber with a telescoping probe that is displaceable to sweep across a surface of the substrate, in accordance with an embodiment.

FIG. 2 is a schematic of a sensor that may be used in the chambers described above, in accordance with an embodiment.

FIG. 3 is a graph of the temperature of the catalytic wire in the sensor of FIG. 2 at different plasma settings, in accordance with an embodiment.

FIG. 4 is a block diagram of the architecture of a plasma processing tool with a plasma behavior model as part of the digital twin of the processing tool, in accordance with an embodiment.

FIG. 5 is a flow diagram depicting a process for training the plasma behavior model, in accordance with an embodiment.

FIG. 6 illustrates a block diagram of an exemplary computer system that may be used in conjunction with a processing tool, in accordance with an embodiment.

### DETAILED DESCRIPTION

Systems described herein include a method and apparatus for measuring radicals in a plasma process and using the recorded information to build a plasma model for a digital twin. In the following description, numerous specific details are set forth in order to provide a thorough understanding of embodiments. It will be apparent to one skilled in the art that embodiments may be practiced without these specific details. In other instances, well-known aspects are not described in detail in order to not unnecessarily obscure embodiments. Furthermore, it is to be understood that the various embodiments shown in the accompanying drawings are illustrative representations and are not necessarily drawn to scale.

As noted above, semiconductor processing environments include many different knobs that can be tuned in order to obtain a desired outcome on a substrate, such as a semiconductor wafer. To further complicate matters, process drift adds to the difficulty of processing substrates while meeting desired uniformity specifications. Accordingly, embodiments disclosed herein include the use of a digital twin to aid in the processing of the substrates. The digital twin can be used to monitor process drift and provide changes to one or more processing knobs in order to counteract drifting conditions within a chamber. The digital twin may also be used to identify when planned maintenance (PM) is needed in order to correct for process drift.

In an embodiment, the digital twin may include a statistical model and a physical model. In embodiments that include a plasma process, a plasma behavior model may also be included as part of the digital twin. In an embodiment, the plasma behavior model may be trained by using one or more sensors in the chamber to provide radical and/or ion maps. For example, a Pirani type sensor may be used in order to identify the radical concentration within the chamber. In one embodiment, the sensor is at the end of a telescoping probe. Such an embodiment allows for a one-dimensional map of the radical concentration across the width of the substrate. In a different embodiment, a plurality of telescoping probes are used to provide a two-dimensional map of the radical concentration over the substrate. In yet another embodiment, a telescoping sensor that can sweep across the surface of the substrate is used in order to provide a two-dimensional map of the radical concentration.

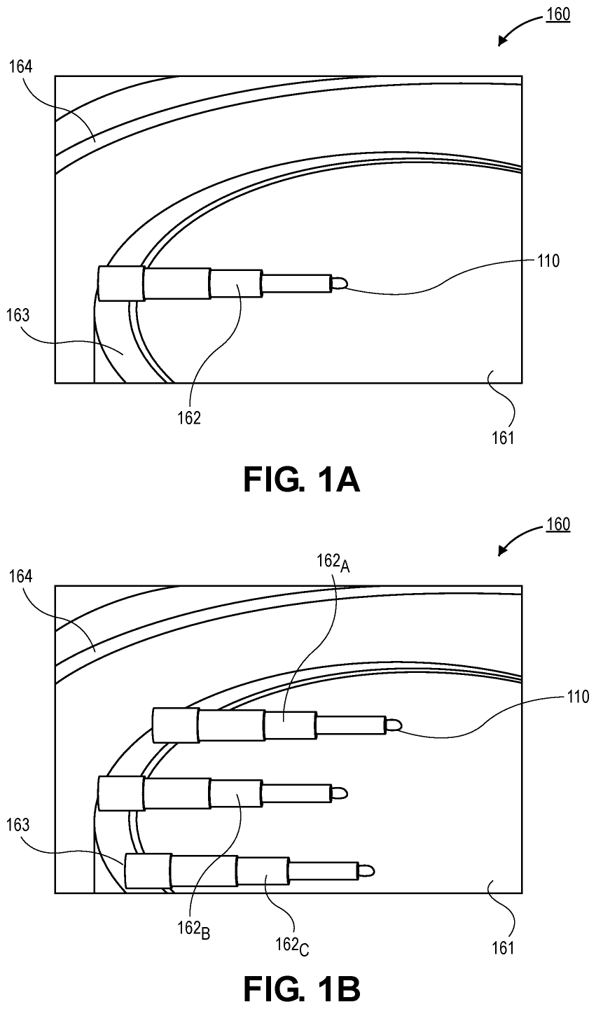

Referring now to FIG. 1A a perspective view illustration of a portion of a plasma chamber 160 is shown, in accordance with an embodiment. In an embodiment, a substrate 161 is supported in the chamber 160. For example, the substrate 161 may be a semiconductor substrate, such as a silicon wafer. An edge ring 163 may surround a perimeter of the substrate 161. A chamber wall 164 may surround a perimeter of the edge ring 163.

In an embodiment, a probe 162 may be attached to the edge ring 163. The probe 163 may be configured to extend out over a surface of the substrate 161. At an end of the probe 162 over the substrate 161, a sensor 110 may be provided. While the probe 162 is shown as being attached to the edge ring 163, it is to be appreciated that the probe 162 may be coupled to any surface within the plasma chamber 160.

In a particular embodiment, the sensor 110 comprises a catalytic wire. The catalytic wire may be a platinum wire or a nickel wire in some embodiments. In an embodiment, the probe 162 may further comprise a second catalytic wire (not shown) that is coated with a non-catalytic layer, such as SiO₂ or Al₂O₃. The coated second catalytic wire may alternatively be provided on a different probe (not shown in FIG. 1A). As will be described in greater detail below, the catalytic wire may be used to measure the concentration of radical species in the chamber 160. For example, the catalytic wire may initiate recombination of radical species. The recombination results in a temperature increase in the catalytic wire. The increase in temperature can be correlated to the resistance of the catalytic wire, which can be measured. Other embodiments may include a sensor 110 for measuring ion energy distributions within the chamber 160. While a sensor 110 with a catalytic wire is shown, it is to be appreciated that the sensor may be any suitable sensor for measuring a parameter of a plasma within the chamber 160. For example, the sensor 110 may be an optical sensor in some other embodiments.

As illustrated in FIG. 1A, the probe 162 may be a telescoping probe 162. That is, the probe 162 may extend out across the substrate 161 from edge to edge, and the probe may fully retract so that no portion of the probe 162 or sensor 110 is above the substrate 161. In such an embodiment, the sensor 110 may be used to provide a one-dimensional map of radical concentration and/or ion energy distribution. That is, sensor 110 readings may be provided as the sensor 110 extends linearly across the surface of the substrate 161. In a particular embodiment, the probe 162 extends across a diameter of substrate (i.e., the sensor 110 passes over a center point of the substrate 161).

In an embodiment, the probe 162 may be coupled to an external computing system that stores data and/or controls the sensor. One or more wires at the end of probe attached to the edge ring 163 may pass through a vacuum feedthrough through the chamber wall 164 or pass over an O-ring (not shown) between a chamber lid (not shown) and the chamber wall 164. In other embodiments, wireless communication may be used to couple the sensor 110 to an external computing device.

Referring now to FIG. 1B, a perspective view illustration of a plasma chamber 160 is shown, in accordance with an additional embodiment. The plasma chamber 160 may be similar to the plasma chamber 160 in FIG. 1A, with the addition of extra probes 162 and sensors 110. For example, three probes 162_{A}-162_{C} are shown in FIG. 1B. However, it is to be appreciated that any number of probes 162 may be used to provide a desired spatial resolution of the radical density and/or ion energy distribution. That is, each of the probes 162 may provide a line scan across the substrate 161, and the plurality of line scans can be put together to provide a two-dimensional map of the radicals and/or ions within the plasma chamber 160 during a plasma process.

Referring now to FIG. 1C, a perspective view illustration of a plasma chamber 160 is shown, in accordance with an additional embodiment. In addition to being a telescoping probe 162, the probe 162 may be scanned across the surface of the substrate 161, as indicated by the dashed arrows. For example, the probe 162 may be swept across the surface of the substrate 161 similar to a windshield wiper in some embodiments. The sweeping motion may be combined with extension and retraction of the probe 162 in order to cover the entire substrate 161. Such an embodiment may allow for an entire two-dimensional map of radical density and/or ion energy distribution to be generated with a single probe 162 and sensor 110.

In yet another embodiment, a plurality of sensors 110 may be provided on a displaceable structure. When in use, the displaceable structure may move the plurality of sensors 110 over the surface of the substrate 161 (or over a dummy substrate or a substrate holder with no substrate). In an embodiment, the plurality of sensors 110 may be arranged to provide a one-dimensional or two-dimensional map of the radical density and/or ion energy distribution. When not in use, the structure may be displaced so that no component is provided above the substrate 161. In this manner, the sensors 110 can provide one-dimensional or two-dimensional maps without a scanning process.

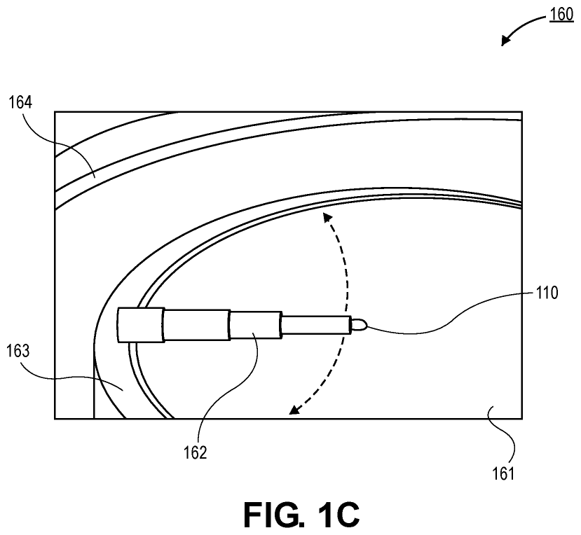

Referring now to FIG. 2, a schematic illustration of a sensor 200 is shown, in accordance with an embodiment. The sensor 200 may be used as the sensor 110 at the end of the probes 162 in FIGS. 1A-1C described in greater detail above. In an embodiment, the sensor 200 comprises a Wheatstone bridge architecture. That is, a set of four resistors 210, 212, 214, and 216 may be electrically coupled to each other in a ring architecture. In an embodiment, the first resistor 210 and the second resistor 212 may be formed by catalytic wires. For example, the catalytic wires may be a material that aids in the recombination of the radical ions. For example, in the case of hydrogen and oxygen radical ions, the first catalytic wires may include platinum or nickel. Of course, plasmas with different species may include other types of catalytic wires.

In an embodiment, the first resistor 210 and the second resistor 212 may be substantially similar to each other. The difference between the first resistor 210 and the second resistor 212 is that the second resistor 212 is covered by a non-catalytic material 215. For example, the second resistor 212 may be coated with a material 215 comprising silicon and oxygen (e.g., SiO₂) or aluminum and oxygen (e.g., Al₂O₃). In an embodiment, the coating 215 is deposited over the second resistor 212 with any suitable deposition process. In a particular embodiment, the coating 215 is provided over the second resistor 212 with an atomic layer deposition (ALD) process. Since the second resistor 212 is coated with coating 215, radical recombination on the second resistor is prevented. As such, the second resistor 212 can be used as a reference value to which the temperature of the first resistor 210 is compared.

In an embodiment, the catalytic wires are heated to a temperature. The voltage required to do this is monitored using the Wheatstone bridge architecture. Changes in the voltage correlate to the temperature change of the catalytic wires induced by radical ion recombination. In an embodiment, there is a linear relationship between the temperature and the resistance of the catalytic wires. As such, changes in resistance can be measured in order to detect a change in temperature. Higher temperatures correlate to higher radical concentrations.

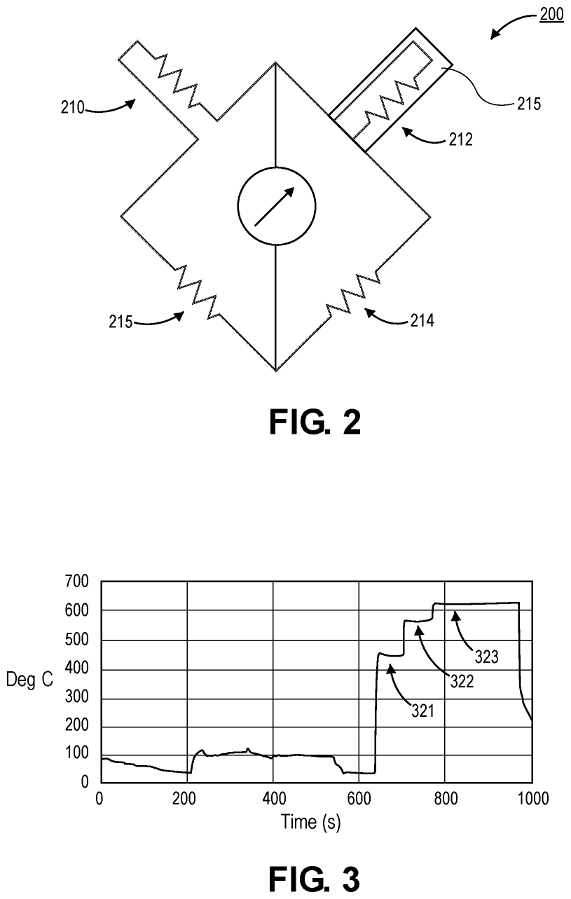

Referring now to FIG. 3, a graph of the temperature of the first catalytic wire 210 over time is shown, in accordance with an embodiment. Up until approximately 625 seconds, the plasma is only an argon plasma. As such, there is no heating due to radical ion recombination. For example, the temperature of the first catalytic wire 210 may be at approximately 100° C. At approximately 625 seconds, processing gasses, such as oxygen and hydrogen, may be added to the chamber. The processing gasses are ionized to form radical ion species. As shown at a first step 321, the temperature of the first catalytic wire 210 increases. A power increase from 1 KW at the first step 321 to 2 KW at the second step 322 results in an increase in the temperature. Further, an increase to 3 KW at the third step 323 results in yet another increase in the temperature. As such, changes to the temperature of the catalytic wire 210 (and thus changes to the resistance of the catalytic wire) can be correlated to changes in the radical ion flux. In an embodiment, the catalytic wire 210 is configured to provide rapid changes in the temperature. This is enabled by having a wire with a low mass. As such, rapid detection of changes to the radical ion flux are possible.

Sensors such as those described in FIG. 2 can be used to generate and train a plasma behavior model. The plasma behavior model can be one component of a digital twin of a processing tool. A digital twin may refer to a model of a physical chamber that exhibits outcomes that substantially match those of the physical chamber. For example, for a given set of inputs provided into the physical chamber and the digital twin, both the physical chamber and the digital twin will output substantially the same substrate outcomes. Due to the similarity between the digital twin and the physical chamber, process optimization, drift detection, planned maintenance scheduling, and the like can be determined through the use of the digital twin.

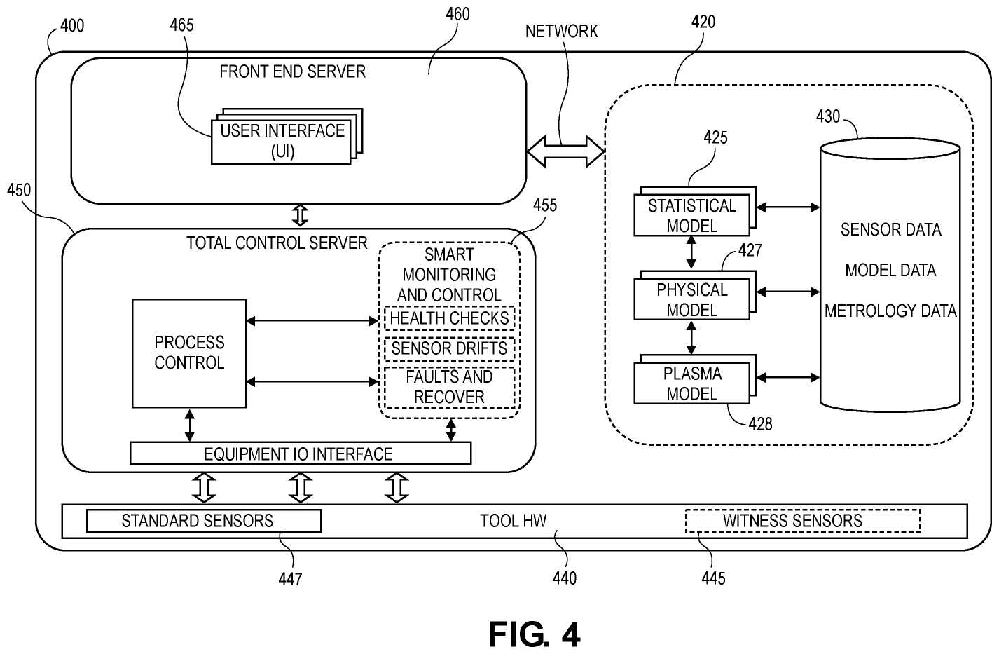

Referring now to FIG. 4, a schematic of a processing tool 400 is shown, in accordance with an embodiment. As shown, a data model server 420 may be integrated with the processing tool 400. For example, the data model server 420 may be communicatively coupled to a front end server 460 by a network connection, as indicated by the arrow. However, in other embodiments, the data model server 420 may be external to the processing tool 400. For example, data model server 420 may be communicatively coupled to the processing tool 400 through an external network or the like.

In some embodiments, the data model server 420 may be referred to as a digital twin of the processing tool. That is, the components of the data model server 420 may represent a virtual copy of the physical processing tool. As such, inputs into the data model server 420 result in outputs that match the outputs demonstrated by the physical processing tool.

In an embodiment, the data model server 420 may comprise a physical model 427, a statistical model 425, and a plasma model 428. The statistical model 425, the physical model 427, and the plasma model 428 may be communicatively coupled to a database 430 for storing input data (e.g., sensor data, model data, metrology data, etc.) used to build and/or update the statistical model 425, the physical model 427, and the plasma model 428.

In an embodiment, the statistical model 425 may be generated by implementing a physical design of experiment (DoE) and use interpolation to provide an expanded process space model. In an embodiment, the physical model 427 may be generated using real world physics and chemistry relationships. For example, physics and chemistry equations for various interactions within a processing chamber may be used to build the physics model. In an embodiment, the plasma model 428 may be generated using sensors that detect radical ion concentrations over a substrate. The sensors may be similar to sensors described in greater detail above. In some embodiments, the plasma model 428 may be generated using a one-dimensional radical and/or ion concentration map or a two-dimensional radical and/or ion concentration map.

In an embodiment, the processing tool 400 may comprise a front end server 460, a tool control server 450, and tool hardware 440. The front end server 460 may comprise a user interface 465 for the data model server 420. The user interface 465 provides an interface for a process engineer to utilize the data modeling in order to execute various operations, such as recipe drift monitoring.

The tool control server 450 may comprise a smart monitoring and control block 455. The smart monitoring and control block 455 may comprise modules for providing diagnostics and other monitoring of the processing tool 400. Modules may include, but are not limited to health checks, sensor drift, fault recovery, and leak detection. The smart monitoring and control block 455 may receive data from various sensors implemented in the tool hardware as inputs. The sensors may include standard sensors 447 that are generally present in semiconductor manufacturing tools 400 to allow for operation of the tool 400. For example, the sensors 447 may include control loop sensors. Control loop sensors may include sensors that are part of feedback loops in order to control a set a processing parameters that are used in the processing of substrates. The sensors may also include witness sensors 445 that are added into the tool 400. Witness sensors 445 may include sensors that are outside of the feedback loops. That is, the outputs from the witness sensors 445 are not directly used to control the processing within the chamber.

The witness sensors 445 provide additional information that is necessary for the building of highly detailed data models. For example, the witness sensors may include physical sensors and/or virtual sensors. Virtual sensors may utilize the data obtained from two or more physical sensors and use calculations in order to provide additional sensor data that is generally not obtainable from physical sensors alone. Witness sensors 445 may include any type of sensor, such as, but not limited to, pressure sensors, temperature sensors, gas flow sensors, and gas concentration sensors. In an embodiment, witness sensors 445 may also include the sensors for detecting radical and/or ion concentrations, similar to sensors described in greater detail above. In an embodiment, the smart monitoring and control block 455 may provide data that is used by the data model server 420. In other embodiments, output data from the various witness sensors 445 may be provided directly to the data model server 420.

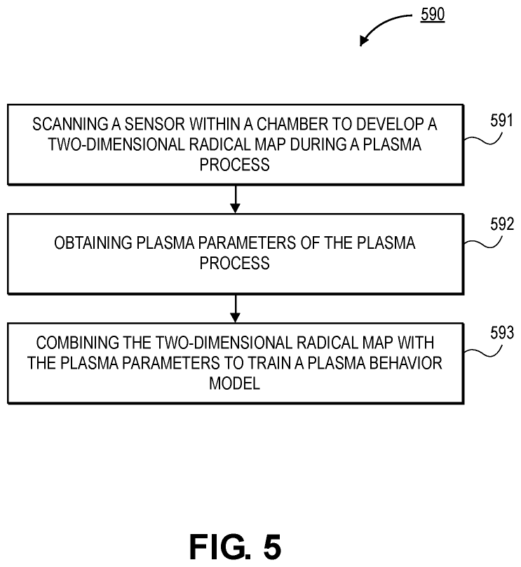

Referring now to FIG. 5, a flow diagram depicting a process 590 for generating a plasma behavior model similar to the plasma model 428 in FIG. 4 is shown, in accordance with an embodiment. In an embodiment, the plasma model 428 is generated using one or more sensors to detect plasma properties within a chamber during a plasma process. For example, the sensors may be configured to provide a one-dimensional or two-dimensional reading of radical and/or ion concentrations above a substrate during the plasma process. The radical and/or ion map may be used in combination with other plasma properties in order to generate the plasma behavior model.

In an embodiment, the process 590 begins with operation 591, which comprises scanning a sensor within a chamber to develop a radical and/or ion map during a plasma process. In some embodiments, the sensor is at the end of a probe. The probe may be a telescoping probe in order to provide a one-dimensional map in some embodiments. That is, the probe may linearly scan the sensor across a width of the substrate. In some embodiments, the line scan may pass the sensor over a center point of the substrate. In other embodiments, a plurality of telescoping probes, each with its own sensor, may be used to provide a two dimensional map. In yet another embodiment, a single telescoping probe may also be scanned (e.g., in a windshield wiper pattern) in order to provide a two dimensional map of the radicals and/or ions. In yet another embodiment, a structure with a plurality of sensors to form a one-dimensional or a two-dimensional map of the radicals and/or ions without a scanning process may be used. In such an embodiment, the structure may be retracted from over the substrate when not in use.

In an embodiment, the sensor or sensors in operation 591 may be similar to the sensors described in greater detail above. For example, the sensors may include Pirani type gauges. In such an embodiment, a pair of catalytic wires are connected as part of a Wheatstone bridge. A first catalytic wire is exposed and a second catalytic wire is surrounded by a non-catalytic coating in order to provide a reference signal to which the first catalytic wire is compared.

In an embodiment, the process 590 may continue with operation 592, which comprises obtaining plasma parameters of the plasma process. In an embodiment, the plasma parameters may include one or more of RF power, microwave power, VSWR, reflected power, and match settings. In some embodiments, data on temperature, pressure, flow rates, temperature, and the like may be collected to form two-dimensional maps and/or other distributions of such properties. The plasma parameters may be detected using control loop sensors, witness sensors, or the settings for various knobs that are controlled to provide a desired plasma outcome.

In an embodiment, process 590 may continue with operation 593 which comprises combining the radical and/or ion map with the plasma parameters to train a plasma behavior model. In an embodiment, combining the radical and/or ion map with the plasma parameters may include associating the plasma parameters with values of the radical and/or ion map. As such, the knowledge of the plasma parameters in subsequent processing operations may be used to generate a radical and/or ion map without needing to use the radical and/or ion sensors.

In an embodiment, the training of the plasma behavior model may be implemented with a DoE. For example, a few standard DoE sets of wafers may provide enough initial data to start off the learning model. Such a model has been shown to converge on process solutions quicker and more tightly than human iterative testing. After the initial training, the radical and/or ion sensors at the end of the probes may be periodically used to obtain data to retrain and/or refine the plasma behavior model. For example, training may occur once per lot, after periods of inactivity in the chamber, at scheduled time intervals (e.g., once per hour, once per day, etc.), or after PM events.

In an embodiment, the plasma process is a plasma etching or plasma deposition process. In other embodiments, the plasma process is a plasma surface treatment. For example, the plasma process may be a nitridation, oxidation, or a wide variety of surface treatments useful in semiconductor manufacturing process flows.

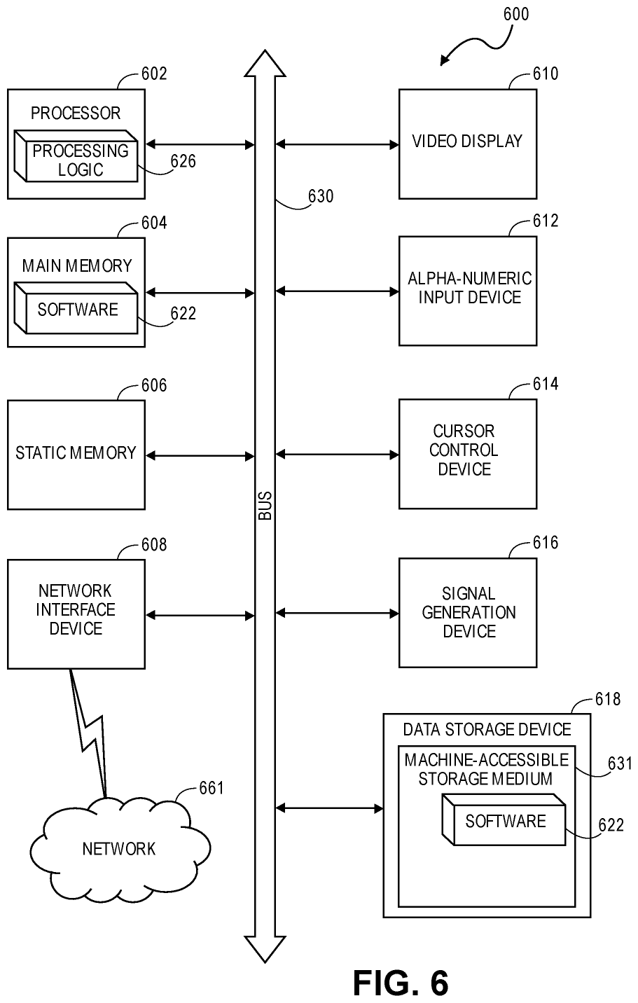

Referring now to FIG. 6, a block diagram of an exemplary computer system 600 of a processing tool is illustrated in accordance with an embodiment. In an embodiment, computer system 600 is coupled to and controls processing in the processing tool. Computer system 600 may be connected (e.g., networked) to other machines in a Local Area Network (LAN), an intranet, an extranet, or the Internet. Computer system 600 may operate in the capacity of a server or a client machine in a client-server network environment, or as a peer machine in a peer-to-peer (or distributed) network environment. Computer system 600 may be a personal computer (PC), a tablet PC, a set-top box (STB), a Personal Digital Assistant (PDA), a cellular telephone, a web appliance, a server, a network router, switch or bridge, or any machine capable of executing a set of instructions (sequential or otherwise) that specify actions to be taken by that machine. Further, while only a single machine is illustrated for computer system 600, the term “machine” shall also be taken to include any collection of machines (e.g., computers) that individually or jointly execute a set (or multiple sets) of instructions to perform any one or more of the methodologies described herein.

Computer system 600 may include a computer program product, or software 622, having a non-transitory machine-readable medium having stored thereon instructions, which may be used to program computer system 600 (or other electronic devices) to perform a process according to embodiments. A machine-readable medium includes any mechanism for storing or transmitting information in a form readable by a machine (e.g., a computer). For example, a machine-readable (e.g., computer-readable) medium includes a machine (e.g., a computer) readable storage medium (e.g., read only memory (“ROM”), random access memory (“RAM”), magnetic disk storage media, optical storage media, flash memory devices, etc.), a machine (e.g., computer) readable transmission medium (electrical, optical, acoustical or other form of propagated signals (e.g., infrared signals, digital signals, etc.)), etc.

In an embodiment, computer system 600 includes a system processor 602, a main memory 604 (e.g., read-only memory (ROM), flash memory, dynamic random access memory (DRAM) such as synchronous DRAM (SDRAM) or Rambus DRAM (RDRAM), etc.), a static memory 606 (e.g., flash memory, static random access memory (SRAM), etc.), and a secondary memory 618 (e.g., a data storage device), which communicate with each other via a bus 630.

System processor 602 represents one or more general-purpose processing devices such as a microsystem processor, central processing unit, or the like. More particularly, the system processor may be a complex instruction set computing (CISC) microsystem processor, reduced instruction set computing (RISC) microsystem processor, very long instruction word (VLIW) microsystem processor, a system processor implementing other instruction sets, or system processors implementing a combination of instruction sets. System processor 602 may also be one or more special-purpose processing devices such as an application specific integrated circuit (ASIC), a field programmable gate array (FPGA), a digital signal system processor (DSP), network system processor, or the like. System processor 602 is configured to execute the processing logic 626 for performing the operations described herein.

The computer system 600 may further include a system network interface device 608 for communicating with other devices or machines. The computer system 600 may also include a video display unit 610 (e.g., a liquid crystal display (LCD), a light emitting diode display (LED), or a cathode ray tube (CRT)), an alphanumeric input device 612 (e.g., a keyboard), a cursor control device 614 (e.g., a mouse), and a signal generation device 616 (e.g., a speaker).

The secondary memory 618 may include a machine-accessible storage medium 632 (or more specifically a computer-readable storage medium) on which is stored one or more sets of instructions (e.g., software 622) embodying any one or more of the methodologies or functions described herein. The software 622 may also reside, completely or at least partially, within the main memory 604 and/or within the system processor 602 during execution thereof by the computer system 600, the main memory 604 and the system processor 602 also constituting machine-readable storage media. The software 622 may further be transmitted or received over a network 620 via the system network interface device 608. In an embodiment, the network interface device 608 may operate using RF coupling, optical coupling, acoustic coupling, or inductive coupling.

While the machine-accessible storage medium 632 is shown in an exemplary embodiment to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine to perform any one or more of the methodologies. The term “machine-readable storage medium” shall accordingly be taken to include, but not be limited to, solid-state memories, and optical and magnetic media.

In the foregoing specification, specific exemplary embodiments have been described. It will be evident that various modifications may be made thereto without departing from the scope of the following claims. The specification and drawings are, accordingly, to be regarded in an illustrative sense rather than a restrictive sense.

What is claimed is:

1. A plasma processing tool, comprising:
a chamber;
a pedestal for supporting a substrate;
an edge ring around a perimeter of the pedestal; and
a sensor at an end of a probe, wherein the probe is configured to extend over the pedestal.

2. The plasma processing tool of claim 1, wherein an end of the probe is coupled to the edge ring.

3. The plasma processing tool of claim 1, wherein the probe is a telescoping probe.

4. The plasma processing tool of claim 1, wherein the probe is configured to be scanned in order to provide a two dimensional map of a parameter being detected by the sensor.

5. The plasma processing tool of claim 4, wherein the parameter being detected is a radical concentration.

6. The plasma processing tool of claim 4, wherein the two dimensional map is used to train a digital twin of the plasma processing tool.

7. The plasma processing tool of claim 6, wherein the digital twin of the plasma processing tool is used to control processing parameters within the plasma processing tool.

8. The plasma processing tool of claim 1, wherein the sensor is a Pirani gauge sensor.

9. The plasma processing tool of claim 8, wherein the Pirani gauge sensor comprises:
a first catalytic wire; and
a second catalytic wire that is coated with a non-catalytic material.

10. The plasma processing tool of claim 9, wherein the first catalytic wire and the second catalytic wire comprise platinum or nickel, and wherein the non-catalytic material comprises silicon and oxygen or aluminum and oxygen.

11. The plasma processing tool of claim 1, further comprising:
a plurality of sensors at ends of a plurality of probes, wherein each of the plurality of probes are configured to extend over the pedestal.

12. A method of training a plasma behavior model, comprising:
scanning a sensor within a plasma chamber to develop a two-dimensional radical map during a plasma process;
obtaining plasma parameters of the plasma process; and
combining the two-dimensional radical map with the plasma parameters to train the plasma behavior model.

13. The method of claim 12, wherein the sensor is scanned above a support for holding a substrate.

14. The method of claim 12, wherein plasma parameters comprises one or more of RF power, microwave power, VSWR, reflected power, and match settings.

15. The method of claim 12, wherein the plasma behavior model is used to predict and/or control process uniformity.

16. The method of claim 15, wherein the process uniformity comprises layer thickness uniformity and/or elemental dose uniformity.

17. The method of claim 12, wherein the plasma behavior model is used in an oxidation process, a nitridation process, or any other surface treatment of a substrate.

18. A semiconductor processing tool, comprising:
a chamber;
a pedestal for supporting a substrate;
an edge ring around a perimeter of the pedestal;
a sensor at an end of a probe, wherein the probe is configured to extend over the pedestal; and
a plasma behavior model, wherein the plasma behavior model is trained by a process, comprising:
scanning the sensor across the pedestal to develop a two-dimensional radical map during a plasma process;
obtaining plasma parameters of the plasma process; and
combining the two-dimensional radical map with the plasma parameters to train the plasma behavior model.

19. The semiconductor processing tool of claim 18, wherein the probe is a telescoping probe.

20. The semiconductor processing tool of claim 18, wherein the sensor comprises a first catalytic wire and a second catalytic wire, wherein the second catalytic wire is coated with a non-catalytic material.
